(19) United States
(12) Patent Application Publication
(10) Pub. No.: US 2008/0225492 A1
(43) Pub. Date: Sep. 18, 2008

(54) Electronic Device and Heat Sink

(75) Inventors: Osamu Murasawa, Tokyo (JP); Ryouichi Kubota, Chiba (JP)

Correspondence Address: KATTEN MUCHIN ROSENMAN LLP, 575 MADISON AVENUE, NEW YORK, NY, 10022-2585, US

(73) Assignee: SONY COMPUTER ENTERTAINMENT INC., Tokyo (JP)

(21) Appl. No.: 12/067,689

(22) PCT Filed: Oct. 5, 2006
(86) PCT No.: PCT/JP2006/320353

§ 371 Date: May 6, 2008

(30) Foreign Application Priority Data
Oct. 13, 2005 (JP) 2005-298875

(51) Int. Cl. H05K 7/20

(52) U.S. Cl. 361/710

(57) ABSTRACT

To provide an electronic device which can prevent that a heat sink constituting a source of the unnecessary radiation of electromagnetic waves with a simple structure. The electronic device which contains the heat sink in the case is constituted.

A heat sink includes: a fin assembly having a wave-guide structure provided with mesh-like openings as a whole and with a plurality of arranged fins and wall portions extending from each of the openings; a heat receiving plate for receiving heat from an electronic device which is a cooled object; and heat pipes. Since each of the openings of the fin assembly has the wave-guide structure, heat generated by the electronic device is dissipated to an exterior through the openings of the fin assembly and an opening section of a case. Leakage of electromagnetic waves to the exterior is prevented by operation of the wave-guide structure.

### TECHNICAL FIELD

The present invention relates to an electronic device equipped with a heat sink for cooling an electronic component such as a processor which generates heat during operation, in particular, a structure of a fin assembly constituting the heat dissipating portion of a heat sink.

### BACKGROUND OF THE INVENTION

In a heat sink mounted to an electronic component, it is a general practice to provide the heat sink with a fin assembly including a large number of fins assembled together so that a surface area of the heat dissipating portion may be enlarged to facilitate diffusion of heat.

In most conventional fin assemblies, a plurality of elongated-plate-like fins are arranged in parallel.

### DISCLOSURE OF THE INVENTION

Since a fin assembly is formed of metal, slot portions defined between individual fins or adjacent fins may constitute antennas to cause unnecessary radiation of electromagnetic waves.

However, in conventional heat sinks, it is solely an improvement in heat radiation efficiency that has been aimed at, and no attempt has been made to prevent the fin assembly itself from constituting a source of unnecessary radiation of electromagnetic waves.

It is therefore an object of the present invention to provide an electronic device which can mitigate influences of unnecessary radiation of electromagnetic waves to an exterior or of electromagnetic waves from the exterior, and a heat sink which is prevented from constituting a source of the unnecessary radiation of electromagnetic waves.

In a fin assembly in which elongated-plate-like fins are arranged in parallel, slot portions between the fins are allowed to operate as slot antennas. That is, when a length of the slots is ½ of certain unnecessary waves, the slot antennas are allowed to radiate the unnecessary waves. Also when the fin assembly is regarded as an electromagnetic shield for an electronic component, a large slot length results in an increase in electromagnetic waves allowed to pass through the same. Thus, as long as it does not hinder the flow of the cooling fluid, it is desirable for the slot length to be minimized. In a case of a wave-guide structure in which a plurality of openings and tubular wall portions are each formed extending from the openings, it is possible to attain an effect of restricting passage of electromagnetic waves.

Based on the above-mentioned speculation, the present invention provides an electronic device including: a case for mounting an electronic apparatus which generates heat; a heat reception medium for absorbing the heat generated by the electronic apparatus mounted in the case; a heat sink provided at a predetermined position in the case; and a heat conduction medium for guiding the heat absorbed by the heat reception medium to the heat sink.

In the electronic device, the heat sink includes a plurality of mesh-like or substantially mesh-like openings formed at a predetermined portion of the case, with tubular wall portions extending from each of the openings, and the heat sink has a wave-guide structure restricting passage of electromagnetic waves traveling from an interior of the case toward an exterior thereof via any one of the openings or electromagnetic waves traveling from the exterior of the case toward the interior thereof via any one of the openings. From the viewpoint of enhancing cooling effect, the electronic device may further include a fan for dissipating the heat conducted to the heat sink to the exterior of the case via the openings.

The present invention also provides a heat sink suitable for use in the electronic device or the like. The heat sink according to the present invention includes a heat sink for dissipating heat generated by an object to be cooled which generates heat, in which the heat sink has a plurality of mesh-like or substantially mesh-like openings and tubular wall portions extending from each of the openings, and exhibits a wave-guide structure restricting passage of electromagnetic waves traveling from any one of the openings toward the associated wall portion or electromagnetic waves traveling from any one of the wall portions toward the associated opening.

More specifically, the heat sink of the present invention is provided with a fin assembly of a wave-guide structure in which a plurality of fins having a predetermined repetitive sectional configuration are aligned to form as awhole a plurality of mesh-like or substantially mesh-like openings and tubular wall portions extending from each of the openings, and in which traveling of electromagnetic waves from any one opening toward the associated wall portion or from any one wall portion toward the associated opening is restricted. Each of the plurality of fins is a plate-like member, for example, of a sectional configuration in which a plurality of raised portions and a plurality of lowered portions appear repeatedly, and the above-mentioned fin assembly is formed by connecting those fins together. The repetitive sectional configuration is a square-wave-like one, and those fins of a square-wave-like sectional configuration are aligned in parallel to each other, with each of the openings being rectangular. The length of the longest inner side of each rectangular opening is smaller than, for example, ½ of the minimum wavelength of unnecessary waves. More preferably, assuming that the length of the above-mentioned inner side is g and that the length of the associated wall portion extending from the opening is d, the following relationship holds true: 27-d/g.

In a heat sink according to another embodiment of the present invention, there are further provided a heat reception medium for absorbing heat generated in the object to be cooled, and a heat conduction medium for guiding the heat absorbed by the heat reception medium to any one of the wall portions.

In the electronic device of the present invention, the heat sink has a mesh-like or substantially mesh-like opening configuration, so, as compared with a fin assembly in which elongated-plate-like fins are arranged in parallel, it is possible to reduce the sloth length, making it possible to prevent the heat sink itself from operating as an unnecessary radiation source of electromagnetic waves; further, the heat sink is capable of functioning as an electromagnetic shield with respect to the object to be cooled.

Further, since it is possible to align a plurality of fins of a predetermined repetitive sectional configuration, the heat sink is easy to produce, and the production cost thereof can be minimized.

### BRIEF DESCRIPTION OF THE DRAWINGS

FIG. 1 is a schematic view of a heat sink according to an embodiment of the present invention.

FIG. 2 is a perspective view illustrating how a plurality of fins are fitted onto a support shaft.

FIG. 3 is an external perspective view of a fin assembly.

FIG. 4 is a diagram illustrating the relationship in terms of shielding effectiveness between gap diagonal distance and frequency in an electronic apparatus.

FIG. 5 is an explanatory view illustrating how electromagnetic waves leak due to a wall portion structure.

FIG. 6 is a diagram illustrating the relationship between opening inner wall length, wall portion length, and shielding effectiveness.

FIG. 7 is an external perspective view of another example of a fin assembly.

FIG. 8 is a schematic diagram illustrating the inner structure of an electronic device building therein a heat sink.

FIG. 9 is a rear view of the electronic device of FIG. 8.

### BEST MODE FOR CARRYING OUT THE INVENTION

In the following, a heat sink according to an embodiment of the present invention will be described with reference to the drawings.

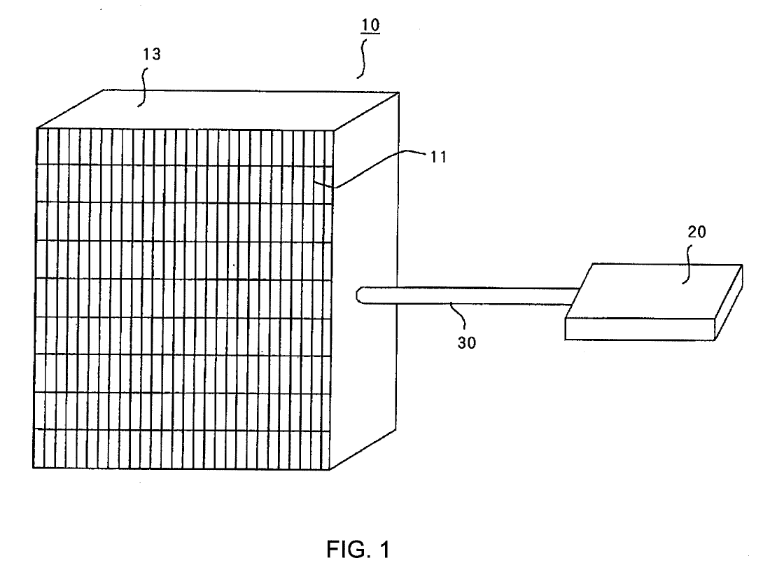

As shown in FIG. 1, the heat sink of this embodiment is equipped with a fin assembly 10 functioning as a heat dissipating portion, a heat receiving plate 20 held in contact with an object to be cooled such as an electronic component (not shown) and adapted to absorb heat generated by the object to be cooled, and a heat pipe 30 connected to the fin assembly 10 and to the heat receiving plate 20. The heat receiving plate 20 may be held in contact with the electronic component to directly absorb heat generated by the electronic component, or may absorb heat generated around an electronic component from the vicinity thereof. The fin assembly 10 may be held in contact with the electronic component, or the fin assembly 10 may be arranged in the vicinity of the electronic component to absorb heat generated around the electronic component.

The fin assembly 10 is formed by arranging a plurality of fins 11 inside a frame 13. As shown in FIG. 1, in the heat sink of this embodiment, heat generated by the object to be cooled is conducted from the heat receiving plate 20 to the fin assembly 10 through the heat pipe 30 to thereby cool the object to be cooled.

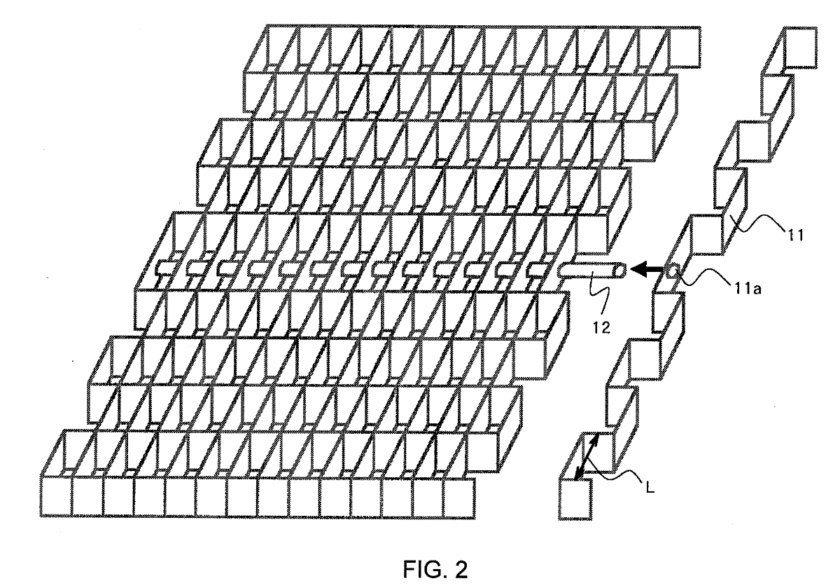

The fin assembly 10 has a structure as shown, for example, in FIG. 2. That is, the fins 11, each of which is formed of a metal plate of a predetermined width and of a repetitive square-wave-like sectional configuration with a plurality of raised portions and a plurality of lowered portions, are bonded together one by one as shown in the drawing, and a support shaft 12 in the form of a hollow cylinder is fitted into a hole 11a formed substantially at the center of each fin 11. The bonding may be effected by conductive adhesive, press-fitting, welding or the like. As a result, the plurality of fins 11 are arranged so as to be parallel to each other, and their sections form as a whole a plurality of mesh-like or substantially mesh-like openings, thereby forming, at the same time, tubular wall portions extending from each of the openings. In principle, all the fins 11 are metal plates of the same configuration and size, which, however, should not be construed restrictively; it is also possible for only a part of them to be metal plates of the same configuration and size. The longitudinal length L of each of the portions corresponding to the inner walls of the repetitive square-wave-like configuration constitutes the length L of the inner wall of each of the rectangular openings when adjacent fins 11 are bonded together therewith.

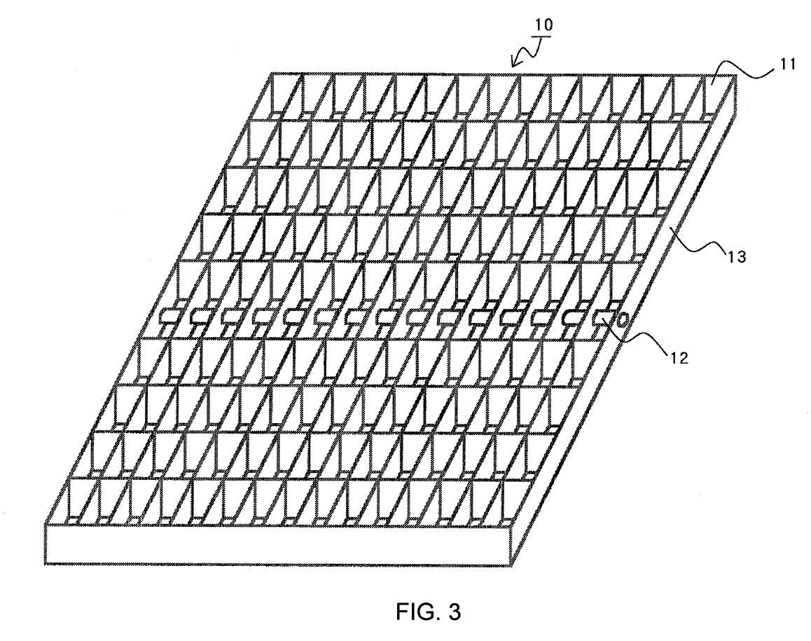

As shown in FIG. 3, the plurality of fins 11, constructed as described above, are accommodated in the frame 13 to thereby form the fin assembly 10.

The frame 13 is equipped with a connection hole corresponding to the holes 11a of the fins 11, and the support shaft 12 is connected to the hollow heat pipe 30 through this connection hole. As a result, heat conducted from the heat receiving plate 20 through the heat pipe 30 is conducted to the fins 11 via the support shaft 12, and is dissipated to the exterior from the fins 11.

One of the features of the fin assembly 10 of this embodiment lines in the structure of the openings and the wall portions extending from the openings. As shown in FIGS. 1 through 3, when, for example, all the fins 11 are of the same configuration and size, alignment of the fins 11 results in formation of the fin assembly 10 as a whole as a plurality of mesh-like or substantially mesh-like openings and tubular wall portions extending from each of the openings. When a portion of the plurality of fins 11 are of the same configuration and size, that portion exhibits the above-mentioned structure.

In particular, in the heat sink of this embodiment, each fin 11 has a square-wave-like sectional configuration. Thus, each of the meshes of the openings is also rectangular. Thus, in the fin assembly 10, each opening is a rectangle with longer and shorter sides, with an associated wall portion extending from the opening by a fixed length to form a rectangular wave-guide structure. The length L of the longer sides of each mesh corresponding to the opening of a rectangular wave-guide (see FIG. 2) is smaller than ½ of the minimum wavelength expected as an unnecessary radiation. As a result, it is possible to prevent the fin assembly 10 from being allowed to unintentionally function as a slot antenna, making it possible to prevent the fin assembly 10 itself from constituting an unnecessary radiation source. Further, it is also possible to attain a shielding effectiveness with respect to a noise of a wavelength larger than 2 L.

In the following, this will be illustrated in detail. A rectangular wave-guide will not allow passage of electromagnetic waves whose cut-off wavelength is not less than λc. The fin assembly 10 of this embodiment utilizes this property of a rectangular wave-guide. The cut-off wavelength λc is a wavelength whose magnitude is double the length of the longer side inner wall length of the rectangular wave-guide. A frequency corresponding to the cut-off wavelength λc is called a cut-off frequency (fc). The cut-off frequency fc can be obtained from the formula: “3×10̂10/λc”. Thus, by arranging the openings of the fin assembly 10 in correspondence with the openings of a rectangular wave-guide and making the longer side inner wall length L of each opening of the fin assembly 10 smaller than ½ of the minimum wavelength of an unnecessary electromagnetic wave radiation, it is possible to obtain a shielding effectiveness against an unnecessary radiation.

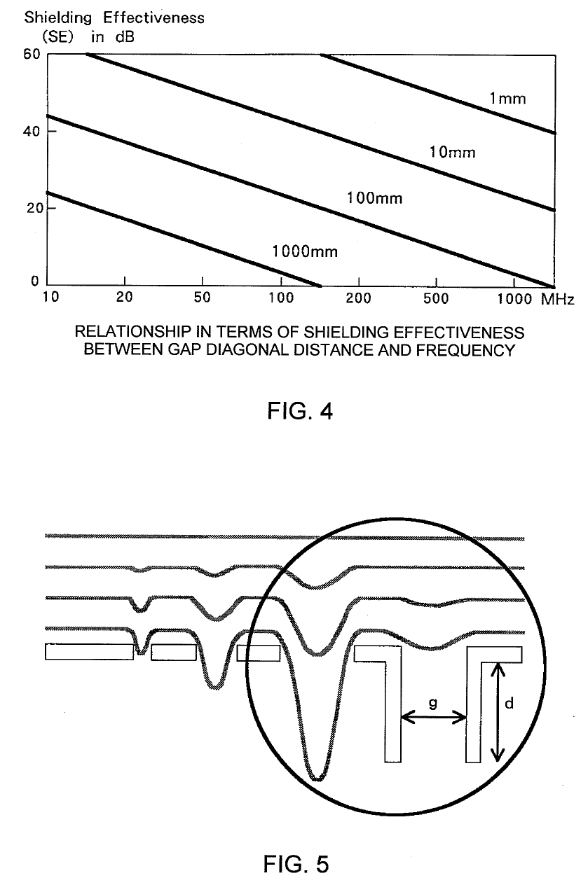

The electromagnetic compatibility (EMC) standard is a standard taking into consideration the influence of electromagnetic waves on electronic apparatuses. In designing an electronic apparatus, it is not so difficult to obtain a shielding effectiveness satisfying the EMC standard if the presence of gaps and an interface cable leading to the exterior is ignored. However, an actual electronic apparatus is full of gaps and equipped with an interface cable, so generation of an unnecessary radiation of electromagnetic waves is inevitable. FIG. 4 shows by way of example the relationship in terms of shielding effectiveness between gap diagonal distance and frequency in an electronic apparatus. In FIG. 4, the horizontal axis indicates frequency, and the vertical axis indicates shielding effectiveness [dB].

When focusing attention solely on the plan-view size of the opening, if it is made not larger than half the wavelength of the cut-off frequency fc, an unnecessary radiation is expected to be prevented. In the case, for example, of a cut-off frequency of 3 [GHz], the cut-off wavelength λc is 100 [mm], and the length L of the longer sides of the opening is 50 [mm]. That is, at a cut-off frequency of 3 [GHz], gaps or holes whose longer side has a length of not more than 50 [mm] must not be formed from the viewpoint of preventing an unnecessary radiation of electromagnetic waves. That, however, is not realistic. In view of this, the length of the associated wall portion extending from the opening is also taken into consideration.

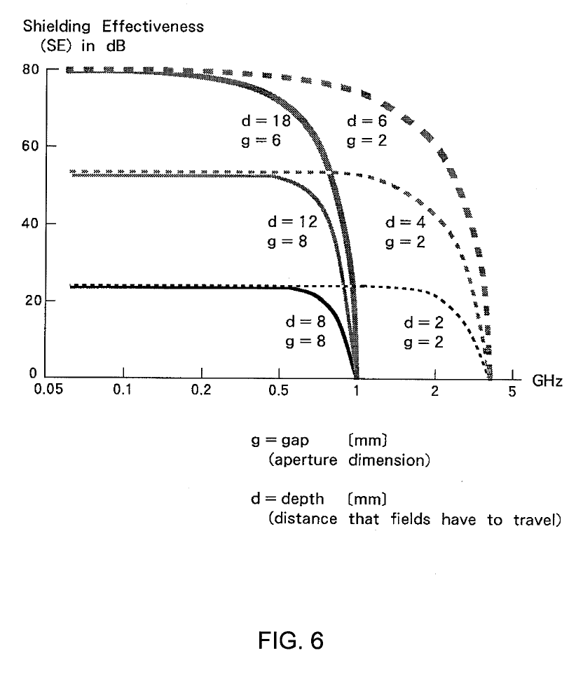

FIG. 5 shows how leakage of electromagnetic waves occurs due to the structure of a wall portion. As the inner diameter of an opening increases, that is, it goes to right-hand side from the left-hand side of a FIG. 5, an opening becomes more subject to leakage of electromagnetic waves from the inner side to the outer side of the opening. However, as shown in the right-hand side portion in FIG. 5 (encircled portion in the drawing), even if the inner diameter of an opening is the same as that of the opening on the left-hand side thereof, if the wall portion associated therewith has a tubular structure, leakage of electromagnetic waves is restrained. The inner diameter g of the opening corresponds to the length L of the longer side mentioned above. FIG. 6 shows the relationship between the length d of the wall portion and the inner diameter g as obtained from actual measurement. In FIG. 6, the horizontal axis indicates cut-off frequency fc [GHz], and the vertical axis indicates shielding effectiveness [dB]. It can be seen from FIG. 6 that an opening size providing a shielding effectiveness for practical use is approximately 27·d/g. While FIG. 5 shows a case in which electromagnetic waves leak from the inner side of an opening, the same principle applies to the reverse case.

In this way, the fin assembly 10 of this embodiment has a wave-guide structure in which passage of electromagnetic waves from the individual openings toward the associated wall portions or from the individual wall portions toward the associated openings is restricted, so it is possible to obtain an electromagnetic wave shielding effectiveness with a simple structure.

In addition, in this embodiment, each mesh has a rectangular configuration, so the length L is easy to specify, and the control of unnecessary radiation suppression and a design intended for that are also facilitated. Further, since a plurality of fins 11 of a repetitive-wave-like configuration are arranged side by side to thereby form mesh-like openings, the fin assembly can be produced easily at low cost.

It is only necessary for the opening configuration to be of a wave-guide structure, which means it is not always necessary for the opening configuration to be a rectangular one but of course it may be of some other configuration such as a square one.

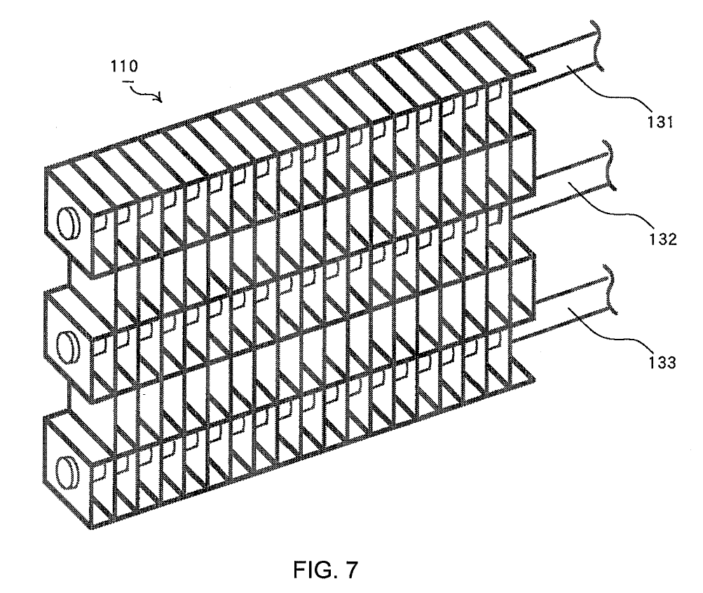

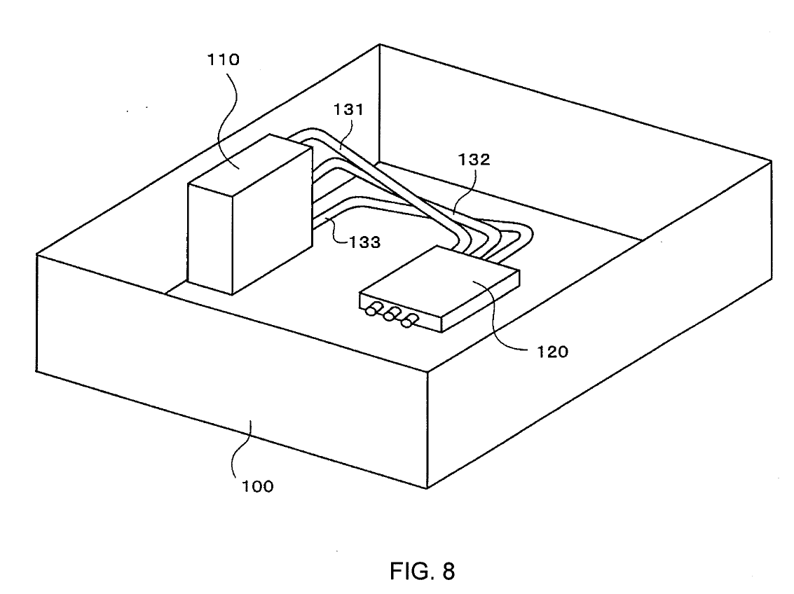

FIG. 7 shows another example of the structure of a fin assembly. This fin assembly 110 is formed by fins of each which have a plurality of holes, and hollow-cylinder-like support shafts are respectively fitted into those holes. As compared with the fin assembly 10 described above, the fin assembly 110 thus constructed helps to achieve a further improvement in terms of heat radiation efficiency. The plurality of support shafts are connected to a heat receiving plate (not shown) through heat pipes 131, 132, and 133, respectively. In this case, the maximum number of heat receiving plates that can be provided is equal to the number of heat pipes.

The heat sink of the present invention is not restricted to the above-mentioned specific structure examples but allows various modifications. For example, it is also possible to arrange a fan in the vicinity of the fin assembly 10, 110 to positively effect heat dissipation from the fin assembly 10, 110 (i.e., to form so-called active type structure). Further, instead of connecting the fin assembly 10, 110 and the heat receiving plate 20 by the heat pipe 30, it is also possible to directly provide the fin assembly 10 on top of the heat receiving plate 20 (or a heat receiving block or the like).

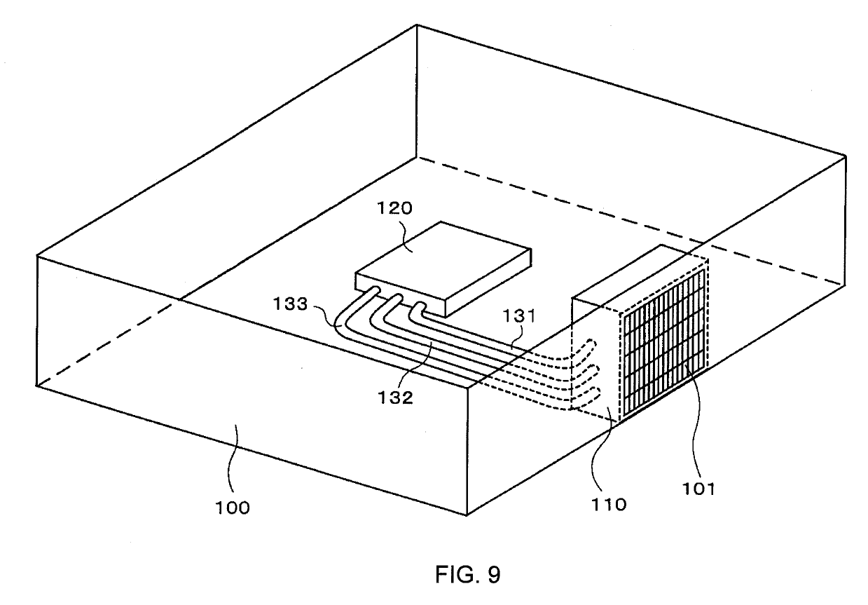

Next, an embodiment of an electronic device building therein a heat sink according to the present invention will be described with reference to FIGS. 8 and 9. FIG. 8 is a schematic view of the inner structure of an electronic device, and FIG. 9 is a rear view thereof. Here, an example of a heat sink is shown which has a heat receiving plate 120, three heat pipes 131, 132, and 133, and the fin assembly 110. This heat sink is arranged in a case 100 of an electronic device as shown in the drawings. That is, the heat receiving plate 120 is arranged on an electronic apparatus such as a processor board arranged at a predetermined position in the case 100, and heat generated by the processor board is absorbed by the heat receiving plate 120. The heat absorbed by the heat receiving plate 120 is conducted to the fin assembly 110 through the heat pipes 131, 132, and 133.

The fin assembly 110 is attached to a side surface portion of the case 100, with a plurality of mesh-like or substantially mesh-like openings being exposed through an opening section 101 (see FIG. 9) formed in the case. That is, circulation of air is possible between the interior and the exterior of the case 100. As described above, the fin assembly 110 has tubular wall portions extending from each of the openings, thus exhibiting a wave-guide structure restricting passage of electromagnetic waves traveling from the interior of the case 100 to the exterior thereof via the openings of the fin assembly 110 and the opening section 101 of the case, or electromagnetic waves traveling from the exterior of the case 100 to the interior thereof via the opening section 101 of the case.

Although not shown, it is also possible to provide a fan behind the fin assembly 110 and to dissipate the heat conducted to the fin assembly 110 to the exterior of the case 100 via the fan and the opening section 101.

Further, while in the example of the heat sink shown in FIGS. 8 and 9 the heat receiving plate 120 and the fin assembly 110 are connected by three heat pipes 131, 132, and 133, the number of heat pipes may be four or more. When the heat receiving plate 120 is directly attached to the fin assembly 110, no heat pipes are necessary. Further, when the electronic apparatus is in the vicinity of the fin assembly 110, the heat receiving plate 120 may be omitted. Instead of providing a single fin assembly 110, it is also possible to divide it into a plurality of fin assemblies and attach them to the case 100.

1. An electronic device, comprising:
a case for mounting an electronic apparatus which generates heat;
a heat reception medium for absorbing the heat generated by the electronic apparatus mounted in the case;
a heat sink provided at a predetermined position in the case; and
a heat conduction medium for guiding the heat absorbed by the heat reception medium to the heat sink,
wherein the heat sink includes a plurality of mesh-like or substantially mesh-like openings formed at a predetermined portion of the case, with tubular wall portions extending from each of the openings, and
wherein the heat sink has a wave-guide structure restricting passage of electromagnetic waves traveling from an interior of the case toward an exterior thereof via any one of the openings or electromagnetic waves traveling from the exterior of the case toward the interior thereof via any one of the openings.

2. An electronic device according to claim 1, further comprising
a fan for dissipating the heat conducted to the heat sink to the exterior of the case via the openings.

3. A heat sink for dissipating heat generated by an object to be cooled that generates heat,
wherein the heat sink includes a plurality of mesh-like or substantially mesh-like openings and tubular wall portions extending from each of the openings, and
exhibits a wave-guide structure restricting passage of electromagnetic waves traveling from any one of the openings toward the associated wall portion or electromagnetic waves traveling from any one of the wall portions toward the associated opening.

4. A heat sink for dissipating heat generated by an object to be cooled that generates heat,
wherein the heat sink is equipped with a fin assembly which includes a plurality of fins of a predetermined repetitive sectional configuration aligned to form as a whole a plurality of mesh-like or substantially mesh-like openings and tubular wall portions extending from each of the openings, and has a wave-guide structure restricting passage of electromagnetic waves traveling from any one of the openings toward the associated wall portion or electromagnetic waves traveling from any one of the wall portions toward the associated opening.

5. A heat sink according to claim 4,
wherein each of the fins includes a plate-like member of a repetitive sectional configuration with a plurality of raised portions and a plurality of lowered portions, and
wherein the fins are connected together to thereby form the fin assembly.

6. A heat sink according to claim 5,
wherein the repetitive sectional configuration has a square-wave-like configuration,
wherein fins of the square-wave-like sectional configuration are aligned in parallel, and
wherein the individual openings have rectangular configuration.

7. A heat sink according to claim 6,
wherein a length of a longest inner side of the rectangular openings is smaller than ½ of a minimum wavelength of an unnecessary wave.

8. A heat sink according to claim 7, wherein,
assuming that the length of the inner side is g, and that a length of the wall portion extending from the associated opening is d, the following relationship holds true: 27·d/g.

9. A heat sink according to claim 3, further comprising:
a heat reception medium for absorbing heat generated by the object to be cooled; and
a heat conduction medium for guiding the heat absorbed by the heat reception medium to any one of the wall portions.
